(19) United States
(12) Patent Application Publication
(10) Pub. No.: US 2026/0004865 A1
(43) Pub. Date: Jan. 1, 2026

(54) SEMICONDUCTOR MEMORY DEVICE AND STACKED MEMORY DEVICE

(71) Applicant: SAMSUNG ELECTRONICS CO., LTD., Suwon-si (KR)

(72) Inventors: Younghun Kim, Suwon-si (KR); Yongsun Kim, Suwon-si (KR); Hancheon Yun, Suwon-si (KR); Sungyoon Jung, Suwon-si (KR); Daehyun Kim, Suwon-si (KR); Myeongo Kim, Suwon-si (KR)

(21) Appl. No.: 19/019,776

(22) Filed: Jan. 14, 2025

(30) Foreign Application Priority Data
Jun. 28, 2024 (KR) 10-2024-0085463

(51) Int. Cl. G11C 29/12; G11C 29/46

(52) U.S. Cl. CPC G11C 29/12015; G11C 29/46

(57) ABSTRACT

A semiconductor memory device includes a physical region, a direct access region and a power manager. The direct access region interfaces with an external test device directly. The power manager generates an internal power supply voltage based on one of a first power supply voltage, a second power supply voltage and a power supply voltage, and provides the internal power supply voltage to the direct access region. The power manager provides the second power supply voltage to the physical region. The direct access region includes a test interface circuit and the test interface circuit, in a direct access mode, generates an internal clock signal based on an external clock signal, generates an internal test clock signal by latching a test control signal received from the external test device based on the internal clock signal and provides the internal test control signal to the physical region.

### CROSS-REFERENCE TO RELATED APPLICATION

This application claims priority under 35 U.S.C. § 119 to Korean Patent Application No. 10-2024-0085463, filed on Jun. 28, 2024, in the Korean Intellectual Property Office, the disclosure of which is incorporated by reference herein in its entirety.

### BACKGROUND

As semiconductor technology progresses, semiconductor integrated devices, such as packages, have become more integrated with higher performance qualities. To this end, three-dimensional structure and wide input/output (I/O) structures in which a plurality of semiconductor chips are vertically stacked are emerging.

In these emerging technologies, it is desired to ensure that each semiconductor chip in a stacked semiconductor device or a wide I/O structure functions properly.

### SUMMARY

The present disclosure provides a semiconductor memory device including a direct access region that receives an operating voltage individually. The present disclosure further provides a semiconductor memory device and a stacked memory device capable of performing a test in a direct access mode. A test operation can verify whether each semiconductor chip in a stacked semiconductor device or a wide I/O structure is functioning normally.

In some implementations, a stacked memory device is capable of adjusting timing point of transferring test control signals to a physical region.

In a first general aspect, a semiconductor memory device includes: a physical region, a direct access region and a power manager. The physical region interfaces with an external memory controller. The direct access region interfaces with an external test device directly. The power manager generates an internal power supply voltage based on one of a first power supply voltage, a second power supply voltage and a dedicated power supply voltage and supply the internal power supply voltage to the direct access region, the first power supply voltage and the second power supply voltage are provided from an outside and the dedicated power supply voltage is received through a dedicated power pad. The power manager provides the second power supply voltage to the physical region. The direct access region includes a test interface circuit and the test interface circuit, in a direct access mode, generates an internal clock signal based on an external clock signal received from the external test device, generates an internal test clock signal by latching a test control signal received from the external test device based on the internal clock signal and provides the internal test control signal to the physical region.

In a second general aspect, a semiconductor memory device includes: a physical region and a direct access region. The physical region interfaces with an external memory controller. The direct access region interfaces with an external test device directly. The direct access region includes a test interface circuit and the test interface circuit, in a direct access mode, generates an internal clock signal based on an external clock signal received from the external test device, generates a first internal test control signal by latching a test control signal received from the external test device at a first timing point of the internal clock signal, generates a second internal test control signal by latching the first internal test control signal at a second timing point of the internal clock and provides the physical region with one of the first internal test control signal and the second internal test control signal as an internal test control signal. The internal clock signal has different duties at the first timing point and the second timing point.

In a third general aspect, a stacked memory device includes: a buffer die and a plurality of core dies. The buffer die includes an interface circuit and a test interface circuit, the interface circuit communicates with an external host device in a normal mode and the test interface circuit interfaces with an external test device directly in a direct access mode. The plurality of core dies are stacked on the buffer die and are connected to the buffer die through a plurality of through silicon vias (TSVs). The buffer die includes a physical region, a direct access region and a TSV region. The interface circuit is disposed in the physical region, the test interface circuit is disposed in the direct access region and the TSVs are formed in the TSV region. The test interface circuit, in a direct access mode, generates an internal clock signal based on an external clock signal received from the external test device, generates a first internal test control signal by latching a test control signal received from the external test device at a first timing point of the internal clock signal, generates a second internal test control signal by latching the first internal test control signal at a second timing point of the internal clock and provides the physical region with one of the first internal test control signal and the second internal test control signal as an internal test control signal. The internal clock signal has different duties at the first timing point and the second timing point.

Accordingly, when the test is performed on the semiconductor memory device in the direct access mode, the test interface circuit is less sensitive to the power supply voltage and test performance may be enhanced by separating a power region of the memory region and the peripheral circuit region from a power region of the test interface circuit (e.g., the direct access region) and by performing a test with respect to various timing margins by adjusting timing point of transferring the internal test control signal, which is generated by latching test control signal at different timing points of the internal clock signal, to the physical region.

### BRIEF DESCRIPTION OF THE DRAWINGS

FIG. 1 is a block diagram illustrating an example of a semiconductor system.

FIG. 2 is a block diagram illustrating an example of the semiconductor memory device in FIG. 1.

FIG. 3 illustrates a disposition of the peripheral circuit in the semiconductor memory device of FIG. 2.

FIG. 4 is a circuit diagram illustrating an example of the power manager in FIG. 2.

FIG. 5 is a circuit diagram illustrating the comparator in the power manager in FIG. 4.

FIG. 6 is a circuit diagram illustrating an example of the power manager in FIG. 2.

FIG. 7 is a circuit diagram illustrating an example of the power manager in FIG. 3.

FIG. 8 is a diagram for explaining an example of an operation of the power manager of FIG. 7.

FIG. 9 is a block diagram illustrating an example of the test interface circuit in the semiconductor memory device 200 of FIG. 2.

FIG. 10 is a block diagram illustrating an example of the internal clock generator in the test interface circuit of FIG. 9.

FIG. 11 illustrates examples of clock signals of the internal clock generator of FIG. 10.

FIG. 12 is a block diagram illustrating an example of the first input circuit in the test interface circuit of FIG. 9.

FIG. 13 is a block diagram illustrating an example of the first input circuit in the test interface circuit of FIG. 9.

FIG. 14 is a timing diagram illustrating an example operation of the first input circuits of FIG. 12 and FIG. 13.

FIG. 15 illustrates the semiconductor memory device of FIG. 2.

FIG. 16 is a block diagram illustrating an example of the input control circuit in FIG. 15.

FIG. 17 is a diagram illustrating an example of a semiconductor package.

FIG. 18 is a block diagram illustrating an example of the stacked memory device in FIG. 17.

FIG. 19 is a block diagram illustrating an example of the first core die in the stacked memory device of FIG. 18.

FIG. 20 illustrates an example of a first bank array in the first core die of FIG. 19.

FIG. 21 is a block diagram illustrating an example of the buffer die in FIG. 17.

FIG. 22 illustrates an example of the buffer die in FIG. 18.

FIG. 23 is a block diagram illustrating an example of a semiconductor system.

FIG. 24 is a flow chart illustrating an example of a method of testing a semiconductor memory device.

Like reference numerals may refer to like elements throughout this application.

### DETAILED DESCRIPTION

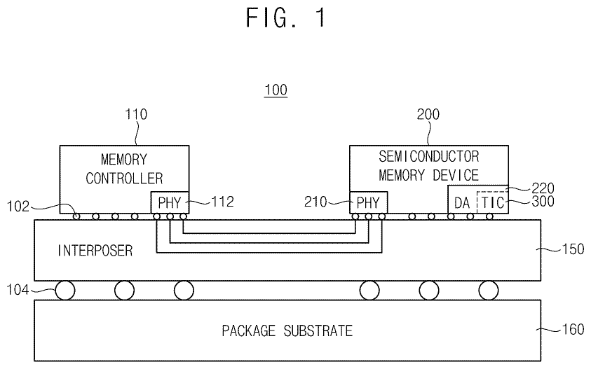

FIG. 1 is a block diagram illustrating an example of a semiconductor system.

Referring to FIG. 1, a semiconductor system 100 includes a memory controller 110, a semiconductor memory device 200, an interposer 1501 and a package substrate 160.

The semiconductor system 100 may be implemented with a form of a multi-chip package, a system-on chip (SoC) or a system in package or may be implemented with a form of a package on package including a plurality packages.

The semiconductor memory device 200 and the memory controller 110 may be mounted onto the interposer 150 through micro-bumps 102. The interposer 150 may be mounted onto the package substrate 160 through bumps 104.

The memory controller 110 may be generally included in diverse processors, such as a central processing Unit (CPU), a graphic processing unit (GPU), and an application processor (AP).

The memory controller 110 may include a physical region PHY 112, the semiconductor memory device 200 may include a physical region 210 and a direct access region DA 220 and the direct access region 220 may include a test interface circuit TIC 300.

The physical region 210 of the semiconductor memory device 200 may be connected to the physical region 112 of the memory controller 110 via the interposer 150. An interface circuit for communication between the semiconductor memory device 200 and the memory controller 110 may be disposed in each of the physical regions 112 and 210. Each of the physical regions 112 and 210 may be referred to as a physical layer.

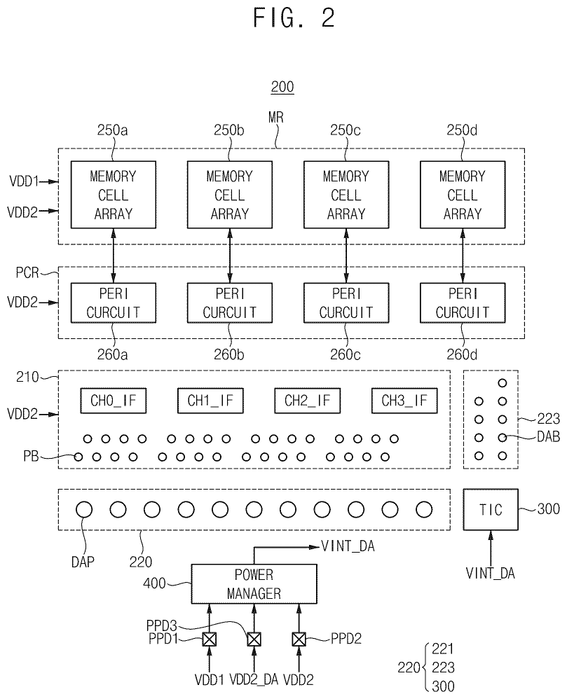

FIG. 2 is a block diagram illustrating an example of the semiconductor memory device in FIG. 1.

Referring to FIG. 2, the semiconductor memory device 200 may include a memory region MR, a peripheral circuit region PCR, the direct access region 220 and a power manager 400.

The memory region MR may include a plurality of memory cell arrays 250a, 250b, 250c and 250d and each of the plurality of memory cell arrays 250a, 250b, 250c and 250d may store data.

The peripheral circuit region PCR may include a plurality of peripheral circuits (“PERI CIRCUIT” in FIGS. 2) 260a, 260b, 260c and 260d and each of the plurality of peripheral circuits 260a, 260b, 260c and 260d may control respective one of the plurality of memory cell arrays 250a, 250b, 250c and 250d.

The physical region 210 may include a plurality of channel interface circuits CH0_IF, CH1_IF, CH2_IF and CH3_IF and each of the plurality of channel interface circuits CH0_IF, CH1_IF, CH2_IF and CH3_IF may interface with respective one of the plurality of memory cell arrays 250a, 250b, 250c and 250d through respective one of the plurality of peripheral circuits 260a, 260b, 260c and 260d. A plurality of PHY bumps PB for interfacing with the memory controller 110 may be formed on the physical region 210.

The direct access region 220 may include a DA bump region 223, a DA probing region 221 and the test interface circuit 300.

In the DA bump region 223, a plurality of DA bumps DAB for interfacing with the external test device through the interposer 150 to test the semiconductor memory device 200, may be formed. In the DA probing region 221, a plurality of DA pads DAP for interfacing with the external test device without going through the interposer 150 to test the semiconductor memory device 200, may be formed. The PHY bumps PB and the DA bumps DB may be formed of micro-bumps, and the DA pads DAP may be formed of pad larger than the micro-bumps. For example, the DA pads DAP may be larger in physical size but fewer in number compared to the PHY bumps PB and the DA bumps DB. In FIG. 2, the DA probing region 221 is formed under the physical region 210 and the DA bump region 223 is formed in a side of the physical region 210. However, the DA bump region 223 and the DA probing region 221 may be variously disposed.

A test operation may be performed by entering a direct access mode to test the semiconductor memory device 200. In the direct access mode, a test data may be applied through the DA bumps DAB or the DA pads DAP of the direct access region 220. The applied test data may be transferred to the physical region 210 and may be provided to each of the plurality of memory cell arrays 250a, 250b, 250c and 250d via an interface circuit in the physical region 210.

The test interface circuit 300, in the direct access mode, may receive an external clock signal and a test control signal from an external test device, may generate an internal clock signal based on the external clock signal, may generate a first internal test control signal by latching the test control signal at a first timing point of the internal clock signal, may generate a second internal test control signal by latching the first internal test control signal at a second timing point of the internal clock and may provide the physical region 210 with one of the first internal test control signal and the second internal test control signal as an internal test control signal. The internal clock signal may have different duties at the first timing point and the second timing point and a frequency of the internal clock signal may be two times greater than a frequency of the external clock signal.

Therefore, the semiconductor memory device 200, in the direct access mode, may perform a high-speed test while adjusting a timing point of transferring the internal clock signal to the physical region 210.

The power manager 400 may receive a first power supply voltage VDD1 through a first power pad PPD1, may receive a second power supply voltage VDD2 through a second power pad PPD2, may generate an internal power supply voltage VINT_DA based on one of the first power supply voltage VDD1 and the second power supply voltage VDD2 and may supply the internal power supply voltage VINT_DA to the direct access region 220.

The first power supply voltage VDD1 and the second power supply voltage VDD2 may be supplied to the memory region MR and the plurality of memory cell arrays 250a, 250b, 250c and 250d may operate based on the first power supply voltage VDD1 and the second power supply voltage VDD2. The second power supply voltage VDD2 may be supplied to the peripheral circuit region PCR and the physical region 210 and the peripheral circuit region PCR and the physical region 210 may operate based on the second power supply voltage VDD2.

A voltage level of the first power supply voltage VDD1 may be greater than a voltage level of the second power supply voltage VDD2.

In some implementations, the power manager 400 may receive a dedicated power supply voltage VDD2_DA through a dedicated power pad PPD3, may generate the internal power supply voltage VINT_DA by power-gating the dedicated power supply voltage VDD2_DA and provide the internal power supply voltage VINT_DA to the direct access region 220.

In some implementations, the semiconductor memory device 200 may be a low latency wide (LLW) I/O memory device.

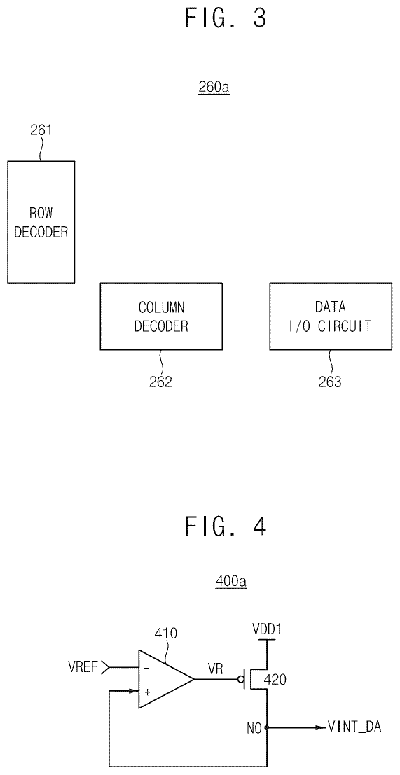

FIG. 3 illustrates a disposition of the peripheral circuit in the semiconductor memory device of FIG. 2.

Referring to FIG. 3, the peripheral circuit 260a includes a row decoder 261, a column decoder 262 and a data I/O circuit 263. The memory cell array 250a in FIG. 2 may be disposed between the row decoder 261 and the column decoder 262. The peripheral circuit 260a may further include a clock buffer, an I/O gating circuit, a bank control logic and a sense amplifier, which are each associated with accessing the memory cell array 250a.

FIG. 4 is a circuit diagram illustrating an example of the power manager in FIG. 2.

Referring to FIG. 4, a power manager 400a includes a comparator 410 and a power transistor 420.

The power transistor 420 may be coupled between the first power supply voltage VDD1 and an output node NO and may generate the internal power supply voltage VINT_DA at the output node NO by regulating the first power supply voltage VDD1 based on a regulation voltage VR. The power transistor 420 may include a p-channel metal-oxide semiconductor (PMOS) transistor that has a source coupled to the first power supply voltage VDD1, a gate to receiving the regulation voltage VR and a drain coupled to the output node NO and providing the internal power supply voltage VINT_DA.

The comparator 410 may generate the regulation voltage VR by comparing a reference voltage VREF and the internal power supply voltage VINT_DA and may apply the regulation voltage VR to the gate of the power transistor 420. The comparator 410 may have a negative input terminal receiving the regulation voltage VR, a positive input terminal receiving the internal power supply voltage VINT_DA and an output terminal providing the regulation voltage VR.

The comparator 410 and the power transistor 420 may constitute a low-drop out (LDO) regulator.

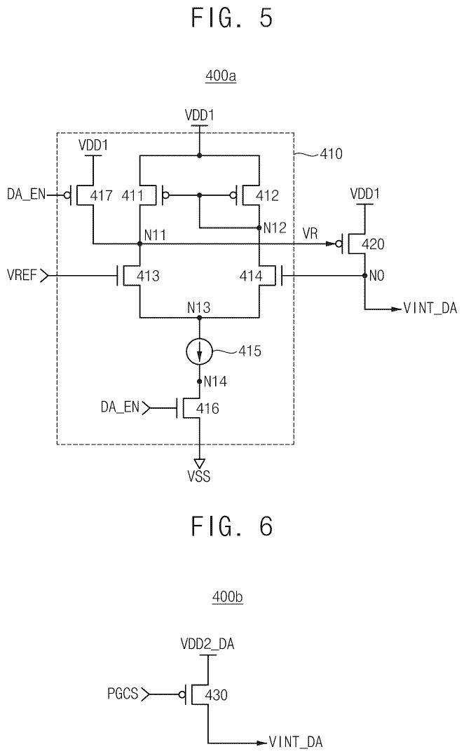

FIG. 5 is an example circuit diagram illustrating the comparator in the power manager in FIG. 4.

Referring to FIG. 5, the power manager 400a includes the comparator 410 and the power transistor 420. The comparator 410 includes PMOS transistors 411, 412 and 417, n-channel metal-oxide semiconductor (NMOS) transistors 413, 414 and 416 and a current source 415.

The PMOS transistor 411 may be coupled between the first power supply voltage VDD1 and a first node N11 and may have a gate coupled to a second node N12. The PMOS transistor 411 may be coupled between the first power supply voltage VDD1 and the second node N12 and may have a gate coupled to the first node N11. Therefore, the PMOS transistors 411 and 412 may operate as a current mirror. The PMOS transistor 411 may be coupled between the first power supply voltage VDD1 and the first node N11 in parallel with the PMOS transistor 417 and may have a gate receiving a mode signal DA_EN. The mode signal DA_EN may designate one of a direct access mode and a normal mode, may designate the direct access mode when the mode signal DA_EN has a logic high level and may designate the normal mode when the mode signal DA_EN has a logic low level.

The NMOS transistor 413 may be coupled between the first node N11 and a third node N13 and may have a gate receiving the reference voltage VREF. The NMOS transistor 414 may be coupled between the second node N12 and the third node N13 and may have a gate coupled to the output node NO and receiving the internal power supply voltage VINT_DA.

The current source 415 may be coupled between the third node N13 and a fourth node N14 and may provide a current sinking to a ground voltage VSS when the NMOS transistor 416 is turned-on. The NMOS transistor 416 may be coupled between the fourth node N16 and the ground voltage VSS and may have a gate receiving the mode signal DA_EN. The NMOS transistor 416 may be selectively turned-on based on the mode signal DA_EN. When the mode signal DA_EN designates the direct access mode, the NMOS transistor 416 is turned-on and the current provided from the current source 415 may sink to the ground voltage VSS.

The first node N11 may be coupled to the gate of the power transistor 420. When the mode signal DA_EN designates the normal mode, the PMOS transistor 417 is turned-on, the first node N11 is pre-charged based on the first power supply voltage VDD1 and the power transistor 420 is turned-off based on a voltage level of the first node N11.

When the mode signal DA_EN designates the direct access mode, the PMOS transistor 417 is turned-off, the difference occurs between currents provided to the third node N13 from the first node N11 and the second node N12 due to a voltage difference between the reference voltage VREF and the internal power supply voltage VINT_DA, and a voltage level of the regulation voltage VR may be determined based on the difference of currents. The power transistor 420 may generate the internal power supply voltage VINT_DA at the output node NO by regulating the first power supply voltage VDD1 based on the regulation voltage VR.

FIG. 6 is a circuit diagram illustrating an example of the power manager in FIG. 3.

Referring to FIG. 6, a power manager 400b includes a power transistor 430.

The power transistor 430 may include a PMOS transistor that has a source coupled to a dedicated power supply voltage VDD2_DA, a gate to receive a power gating control signal PGCS and a drain providing the internal power supply voltage VINT_DA.

The power transistor 430 may generate, in response to the power gating control signal PGCS that is activated at a low level in the direct access mode, the internal power supply voltage VINT_DA by power-gating the dedicated power supply voltage VDD2_DA and may cut off the dedicated power supply voltage VDD2_DA in the normal mode.

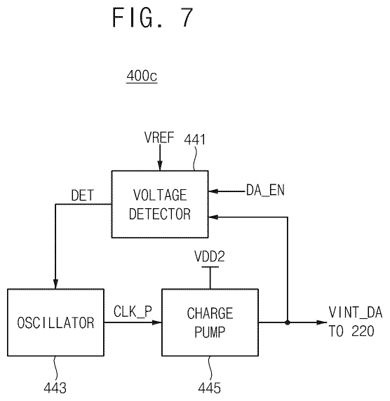

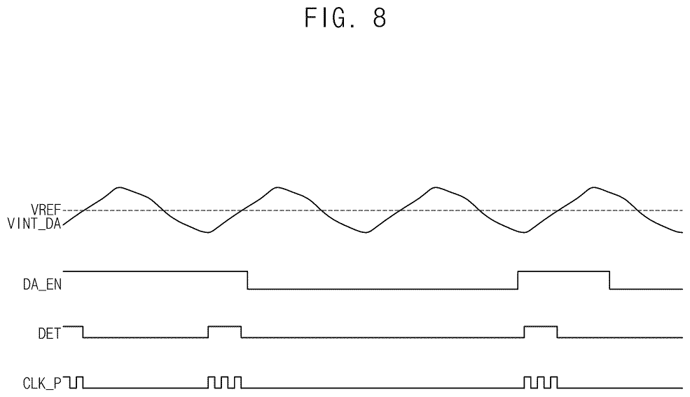

FIG. 7 is a circuit diagram illustrating an example of the power manager in FIG. 3.

Referring to FIG. 7, a power manager 400c includes a voltage detector 441, an oscillator 443 and a charge pump 445.

The voltage detector 441 may receive the mode signal DA_EN and may generate a decision signal DET by comparing the internal power supply voltage VINT_DA with the reference voltage VREF in the direct access mode (e.g., when the mode signal DA_EN designates the direct access mode).

The oscillator 443 may generate a pumping clock signal CLK_P by performing an oscillation operation based on the decision signal DET.

The charge pump 445 may generate the internal power supply voltage VINT_DA by performing a pumping operation based on the pumping clock signal CLK_P and the second power supply voltage VDD2.

FIG. 8 is a diagram for explaining an example of an operation of the power manager 400c of FIG. 7.

Referring to FIGS. 7 and 8, when the mode signal DA_EN designates the direct access mode (e.g., when the mode signal DA_EN has a logic high level), may be enabled and may generate the decision signal DET by comparing the internal power supply voltage VINT_DA with the reference voltage VREF. For example, as illustrated in FIG. 8, the decision signal DET may maintain a high level in a section in which the internal power supply voltage VINT_DA is lower than the reference voltage VREF among the sections in which the internal power supply voltage VINT_DA rises and may maintain a low level in other sections.

The decision signal DET generated by the voltage detector 441 is provided to the oscillator 443, and the oscillator 443 generate the pumping clock signal CLK_P by performing an oscillation operation while the decision signal DET is a high level. As a result, as illustrated in FIG. 8, in the pumping clock signal CLK_P, a signal in the pulse form exists in a section in which the mode signal DA_EN is a high level and the charge pump 445 generates internal power supply voltage VINT_DA and signal in the pulse form does not exist in other sections.

In some implementations, the charge pump 445 may include a plurality of charge pump circuits and a control circuit. Each of the plurality of charge pump circuits may be enabled or disabled by the control circuit and may perform a pumping operation based on the pumping clock signal CLK_P and the second power supply voltage VDD2.

Because the charge pump 445 generates the internal power supply voltage VINT_DA in the direct access mode and does not generate the internal power supply voltage VINT_DA in the normal mode, a voltage level of the internal power supply voltage VINT_DA floats in the normal mode.

In FIGS. 4-8, a level of the internal power supply voltage VINT_DA can be adjusted by the external test device or the memory controller 110, which uses test mode register set (TMRS), fuse settings, or mode register.

The voltage level of the internal power supply voltage VINT_DA may be smaller than the first power supply voltage VDD1 and may be greater than the second power supply voltage VDD2.

As mentioned above with reference to FIGS. 4-8, when the test is performed on the semiconductor memory device 200 in the direct access mode, the test interface circuit 300 is less sensitive to the power supply voltage. Test performance may be enhanced by separating a power region of the memory region MR and the peripheral circuit region PCR from a power region of the test interface circuit 300 (e.g., the direct access region 220).

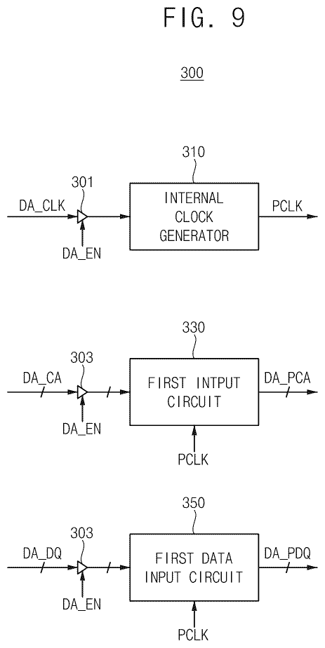

FIG. 9 is a block diagram illustrating an example of the test interface circuit in the semiconductor memory device 200 of FIG. 2.

Referring to FIG. 9, the test interface circuit 300 includes buffers 301, 303 and 305, an internal clock generator 310, a first input circuit 330 and a first data input circuit 350. The first input circuit 330 may be referred to as an input circuit.

The buffer 301 may be enabled in response to the mode signal DA_EN designating the direct access mode and may provide the internal clock generator 310 with an external clock signal DA_CLK received from the external test device. The internal clock generator 310, in the direct access mode, may generate an internal clock signal PCLK based on the external clock signal DA_CLK and may provide the internal clock signal PCLK to the first input circuit 330 and the first data input circuit 350.

The buffer 303 may be enabled in response to the mode signal DA_EN designating the direct access mode and may provide the first input circuit 330 with test control signal DA_CA received from the external test device. The first input circuit 330, in the direct access mode, may generate an internal test control signal DA_PCA by delaying the test control signal DA_CA at least once based on the internal clock signal PCLK.

The test control signal DA_CA may include a command and an address associated with the test.

The buffer 305 may be enabled in response to the mode signal DA_EN designating the direct access mode and may provide the first data input circuit 350 with test data DA_DQ received from the external test device. The first data input circuit 350, in the direct access mode, may generate an internal test data DA_PDQ by latching the test data DA_DQ based on the internal clock signal PCLK.

The internal test control signal DA_PCA and the internal test data DA_PDQ may be provided to the physical region 210 in FIG. 3.

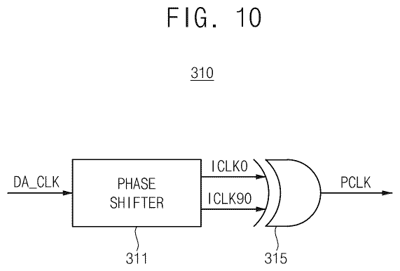

FIG. 10 is a block diagram illustrating an example of the internal clock generator in the test interface circuit of FIG. 9.

Referring to FIG. 10, the internal clock generator 310 includes a phase shifter 311 and an XOR gate 315.

The phase shifter 311 may generate a first intermediate clock signal ICLK0 and a second intermediate clock signal ICLK90 having a phase difference of 90 degrees with respect to each other by shifting a phase of the external clock signal DA_CLK. The XOR gate 315 may generate the internal clock signal PCLK by performing an XOR operation on the first intermediate clock signal ICLK0 and the second intermediate clock signal ICLK90.

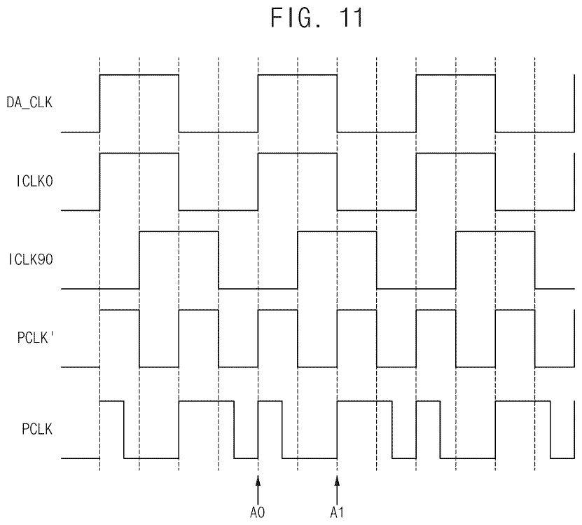

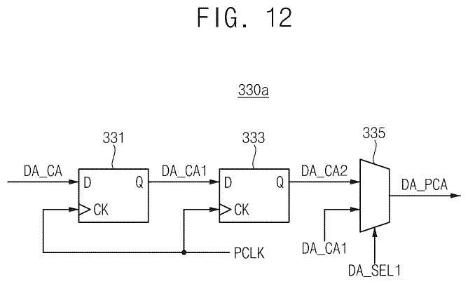

FIG. 11 illustrates examples of clock signals of the internal clock generator of FIG. 10.

Referring to FIGS. 10 and 11, the phase shifter 311 may generate the first intermediate clock signal ICLK0 and the second intermediate clock signal ICLK90 having a phase difference of 90 degrees with respect to each other by shifting the phase of the external clock signal DA_CLK and the XOR gate 315 may generate an internal clock signal PCLK′ by performing an XOR operation on the first intermediate clock signal ICLK0 and the second intermediate clock signal ICLK90. Therefore, a frequency of the internal clock signal PCLK′ may be greater than a frequency of the external clock signal DA_CLK.

In FIG. 11, the internal clock signal PCLK′ may denote an ideal internal clock signal generated by the phase shifter 311 (e.g., an internal clock signal that is not affected by an outside or is not physically influenced by the phase shifter 311 and/or the XOR gate 315) and the internal clock signal PCLK may denote an internal clock which is physically influenced by the phase shifter 311 and/or the XOR gate 315 or influenced by a transmission path of the direct access region 220.

Because the above influence can cause a duty of the internal clock signal PCLK to be distorted, the internal clock signal PCLK may have different duties at a first timing point A0 and a second timing point A1. For example, a duty ratio of the internal clock signal PCLK may be smaller than 50% at the first timing point A0 and a duty ratio of the internal clock signal PCLK may be greater than 50% at the second timing point A1.

The test control signal DA_CA received from the external test device may have a different margin when the test control signal DA_CA is latched at the first timing point A0 compared to when the test control signal DA_CA is latched at the second timing point A1. The external test device cannot select the first timing point A0 and the second timing point A1, and the semiconductor memory device 200 is tested based on the test control signal applied at each of the first timing point A0 and the second timing point A1.

FIG. 12 is a block diagram illustrating an example of the first input circuit in the test interface circuit of FIG. 9.

Referring to FIG. 12, a first input circuit 330a includes a first D-flipflop 331, a second D-flipflop 333 and a multiplexer 335. Each of the first D-flipflop 331 and the second D-flipflop 333 may include an input terminal D, an output terminal Q and a clock terminal CK. The first D-flipflop 331 and the second D-flipflop 333 may constitute a shift register.

The first D-flipflop 331 may output a first internal test control signal DA_CA1 by latching the test control signal DA_CA at the first timing point of the internal clock signal PCLK. The first D-flipflop 331 may output the first internal test control signal DA_CA1 by latching the test control signal DA_CA at a rising edge of the internal clock signal PCLK and at the first timing point.

The second D-flipflop 333 may output a second internal test control signal DA_CA2 by latching the first internal test control signal DA_CA1 at the second timing point of the internal clock signal PCLK. The second D-flipflop 333 may output the second internal test control signal DA_CA2 by latching the first internal test control signal DA_CA1 at a rising edge of the internal clock signal PCLK and at the second timing point.

The multiplexer 335 may select one of the first internal test control signal DA_CA1 and the second internal test control signal DA_CA2 based on a selection signal DA_SEL1 and may output the selected one as an internal test control signal DA_PCA. The multiplexer 335 may transfer the internal test control signal DA_PCA to the physical region 210 in FIG. 3.

The selection signal DA_SEL1 may be set by the memory controller 110 or the external test device by using TMRS and may be used for selecting one of the first internal test control signal DA_CA1 and the second internal test control signal DA_CA2.

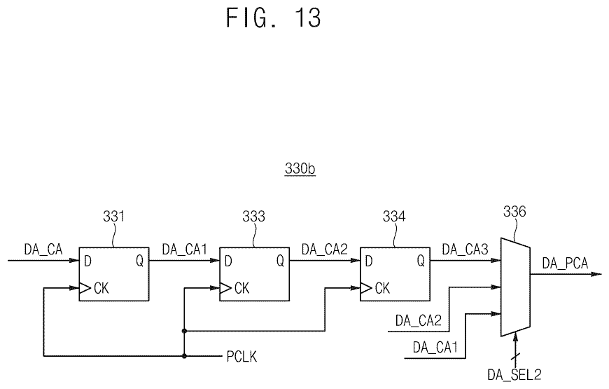

FIG. 13 is a block diagram illustrating an example of the first input circuit in the test interface circuit of FIG. 9.

Referring to FIG. 13, a first input circuit 330b includes a first D-flipflop 331, a second D-flipflop 333, a third D-flipflop 334 and a multiplexer 336. Each of the first D-flipflop 331, the second D-flipflop 333 and the third D-flipflop 334 may include an input terminal D, an output terminal Q and a clock terminal CK. The first D-flipflop 331 and the second D-flipflop 333 may constitute a shift register.

The first D-flipflop 331 may output a first internal test control signal DA_CA1 by latching the test control signal DA_CA at the first timing point of the internal clock signal PCLK. The first D-flipflop 331 may output the first internal test control signal DA_CA1 by latching the test control signal DA_CA at a rising edge of the internal clock signal PCLK and at the first timing point.

The second D-flipflop 333 may output a second internal test control signal DA_CA2 by latching the first internal test control signal DA_CA1 at the second timing point of the internal clock signal PCLK. The second D-flipflop 333 may output the second internal test control signal DA_CA2 by latching the first internal test control signal DA_CA1 at a rising edge of the internal clock signal PCLK and at the second timing point.

The third D-flipflop 334 may output a third internal test control signal DA_CA3 by latching the second internal test control signal DA_CA2 at a third timing point of the internal clock signal PCLK. The third D-flipflop 334 may output the third internal test control signal DA_CA3 by latching the second internal test control signal DA_CA2 at a rising edge of the internal clock signal PCLK and at the third timing point.

The multiplexer 336 may select one of the first internal test control signal DA_CA1, the second internal test control signal DA_CA2 and the third internal test control signal DA_CA3 based on a selection signal DA_SEL2 and may output the selected one as an internal test control signal DA_PCA. The multiplexer 336 may transfer the internal test control signal DA_PCA to the physical region 210 in FIG. 3.

The selection signal DA_SEL2 may be set by the memory controller 110 or the external test device by using TMRS and may be used for selecting one of the first internal test control signal DA_CA1, the second internal test control signal DA_CA2 and the third internal test control signal DA_CA3.

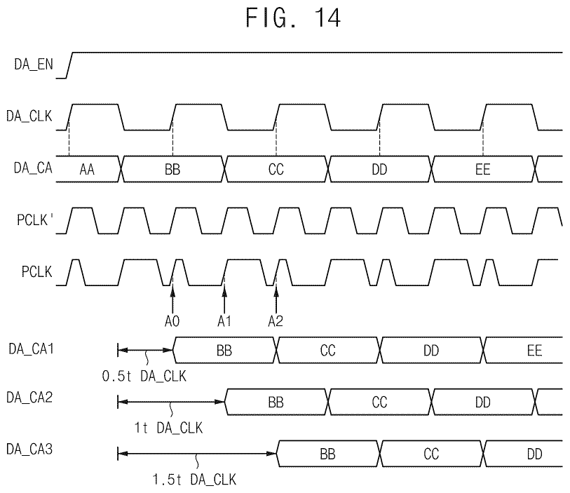

FIG. 14 is a timing diagram illustrating an example operation of the first input circuits of FIGS. 12 and 13.

In FIG. 14, it is assumed that the first input circuit 330a and the first input circuit 330b operate based on the internal clock signal PCLK instead of the internal clock signal PCLK′ and the mode signal DA_EN has a logic high level (‘H’).

Hereinafter, an example operation of the first input circuits 330a and 330b of FIG. 12 and FIG. 13 will be described with reference to FIGS. 9-14.

The external clock signal DA_CLK and the test control signal DA_CA are input the to the internal clock generator 310 and the first input circuit 330 from the external test device. The test control signal DA_CA may include consecutive signals AA, BB, CC, DD and EE.

The first D-flipflop 331 may output the first internal test control signal DA_CA1 by latching the test control signal DA_CA at a rising edge of the internal clock signal PCLK and at the first timing point A0. Therefore, the first internal test control signal DA_CA1 may be delayed by a half period 0.5t DA_CLK of the external clock signal DA_CLK with respect to the test control signal DA_CA.

The second D-flipflop 333 may output the second internal test control signal DA_CA2 by latching the first internal test control signal DA_CA1 at a rising edge of the internal clock signal PCLK and at the second timing point A1. Therefore, the second internal test control signal DA_CA2 may be delayed by a period 1t DA_CLK of the external clock signal DA_CLK with respect to the test control signal DA_CA.

The third D-flipflop 334 may output the third internal test control signal DA_CA3 by latching the second internal test control signal DA_CA2 at a rising edge of the internal clock signal PCLK and at the third timing point A2. Therefore, the second internal test control signal DA_CA2 may be delayed by one and a half period 1.5t DA_CLK of the external clock signal DA_CLK with respect to the test control signal DA_CA.

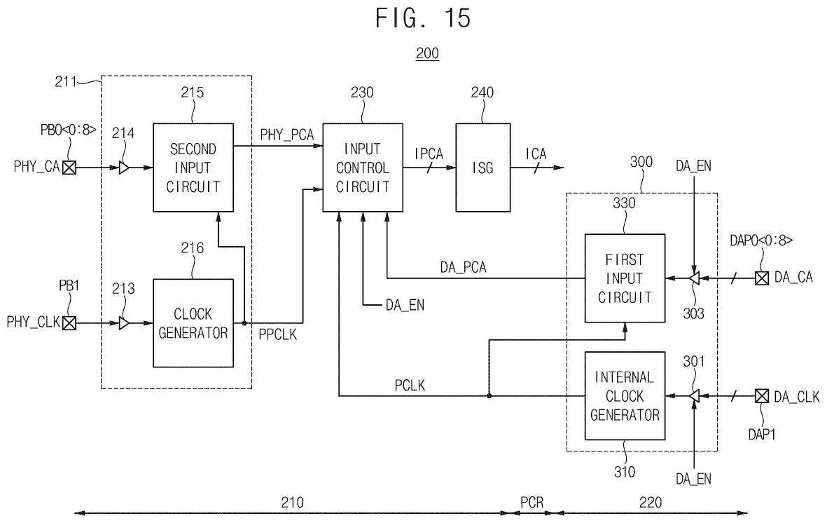

FIG. 15 illustrates the semiconductor memory device of FIG. 2.

Referring to FIG. 15, the semiconductor memory device 200 includes the physical region 210, the direct access region 220 and the peripheral circuit region PCR. In FIG. 15, the memory region MR is not illustrated for simplicity.

A plurality of first PHY bumps PB0<0:8> for receiving a normal control signal PHY_CA and a second PHY bump PB1 for receiving a normal clock PHY_CLK, during a normal operation, may be disposed on the physical region 210. A plurality of first DA pads DAP0<0:8> for receiving the test control signal DA_CA, and a second DA pad DAP1 for receiving the external clock DA_CLK may be disposed on the direct access region 220. The test interface circuit 300 may be disposed in the direct access region 220.

The test interface circuit 300 may include the buffers 301 and 303, the internal clock generator 310 and the first input circuit 330. The buffer 301 may be enabled in response to the mode signal DA_EN designating the direct access mode and may provide the internal clock generator 310 with an external clock signal DA_CLK received from the external test device. The buffer 303 may be enabled in response to the mode signal DA_EN designating the direct access mode and may provide the first input circuit 330 with the test control signal DA_CA received from the external test device.

As mentioned with reference to FIG. 9, the internal clock generator 310, in the direct access mode, may generate an internal clock signal PCLK based on the external clock signal DA_CLK and may provide the internal clock signal PCLK to the first input circuit 330 and an input control circuit 230 in the physical region 210. The first input circuit 330, in the direct access mode, may generate the internal test control signal DA_PCA by delaying the test control signal DA_CA at least once based on the internal clock signal PCLK and may transfer the internal test control signal DA_PCA to the input control circuit 230 in the physical region 210.

The physical region 210 may include an interface circuit 211, the input control circuit 230 and an internal signal generator ISG 240.

The interface circuit 211 may include buffers 213 and 214, a second input circuit 215 and a clock generator 216.

The buffer 213, in the normal mode, may receive a clock signal PHY_CLK and may provide the clock signal PHY_CLK to the clock generator 216. The clock generator 216 may generate a normal clock signal PPCLK based on the clock signal PHY_CLK and may provide the normal clock signal PPCLK to the second input circuit 215 and the input control circuit 230.

The buffer 214, in the normal mode, may receive a normal control signal PHY_CA and may provide the normal control signal PHY_CA to the second input circuit 215. The second input circuit 215 may generate an internal normal control signal PHY_PCA based on the normal clock signal PPCLK and may transfer the internal normal control signal PHY_PCA to the input control circuit 230.

The input control circuit 230 may receive the mode signal DA_EN, the internal clock signal PCLK, the internal test control signal DA_PCA, the normal clock signal PPCLK and the internal normal control signal PHY_PCA.

The input control circuit 230, in response to the mode signal DA_EN designating the direct access mode, may select the internal test control signal DA_PCA of the internal test control signal DA_PCA and the internal normal control signal PHY_PCA, may generate a selected control signal IPCA by latching the internal test control signal DA_PCA based on the internal clock signal PCLK and may provide the selected control signal IPCA to the internal signal generator 240.

The input control circuit 230, in response to the mode signal DA_EN designating the normal mode, may select the internal normal control signal PHY_PCA of the internal test control signal DA_PCA and the internal normal control signal PHY_PCA, may generate a selected control signal IPCA by latching the internal normal control signal PHY_PCA based on the normal clock signal PPCLK and may provide the selected control signal IPCA to the internal signal generator 240.

The internal signal generator 240 may generate internal signals ICA based on the selected control signal IPCA and may provide the internal signals ICA to the peripheral circuit region PCR.

The test interface circuit 300 may generate internal test data by latching test data and may provide the internal test data to the input control circuit 230, the interface circuit 211 may generate an internal normal data by latching normal data and may provide the internal normal data to the input control circuit 230. The input control circuit 230, in the direct access mode, may provide the internal test data to the memory region MR via the peripheral circuit region PCR and, in the normal mode, may provide the internal normal data to the memory region MR via the peripheral circuit region PCR.

The normal control signal PHY_CA and the clock signal PHY_CLK may be provided from the memory controller 110 in FIG. 1 in the normal mode.

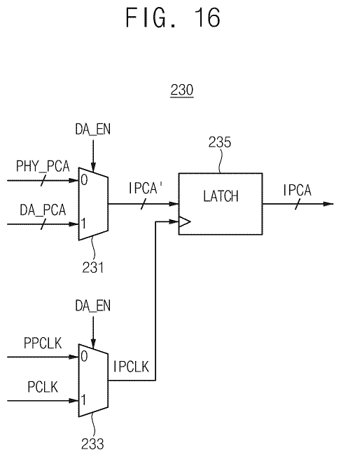

FIG. 16 is a block diagram illustrating an example of the input control circuit in FIG. 15.

Referring to FIG. 16, the input control circuit 230 includes a first multiplexer 231, a second multiplexer 233 and a latch 235.

The first multiplexer 231 may receive the mode signal DA_EN, the internal test control signal DA_PCA and the internal normal control signal PHY_PCA, may select the internal test control signal DA_PCA as a first selected control signal IPCA′ in response to the mode signal DA_EN designating the direct access mode, may select the internal normal control signal PHY_PCA as the first selected control signal IPCA′ in response to the mode signal DA_EN designating the normal mode and may provide the first selected control signal IPCA′ to the latch 235.

The second multiplexer 233 may receive the mode signal DA_EN, the internal clock signal PCLK and the normal clock signal PPCLK, may select the internal clock signal PCLK as a selected clock signal IPCLK in response to the mode signal DA_EN designating the direct access mode, may select the normal clock signal PPCLK as the selected clock signal IPCLK in response to the mode signal DA_EN designating the normal mode and may provide the selected clock signal IPCLK to the latch 235.

The latch 235 may generate the selected control signal IPCA by latching the first selected clock signal IPCA′ at a rising edge of the selected clock signal IPCLK and may provide the selected control signal IPCA to the internal signal generator 240.

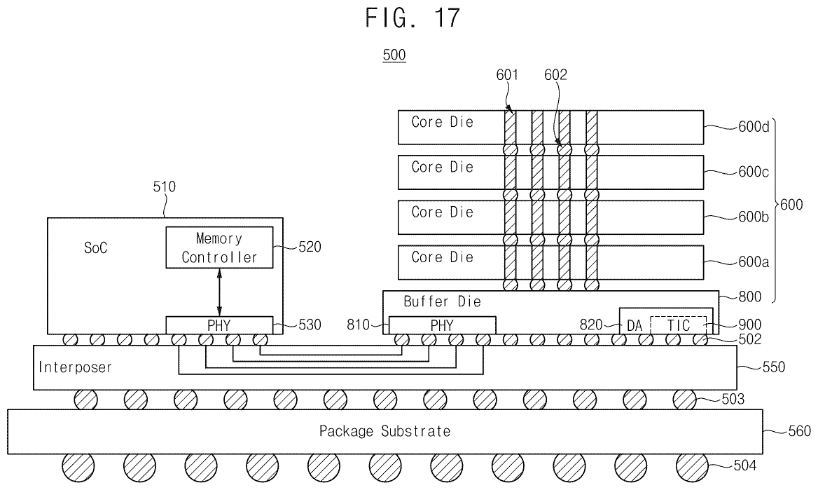

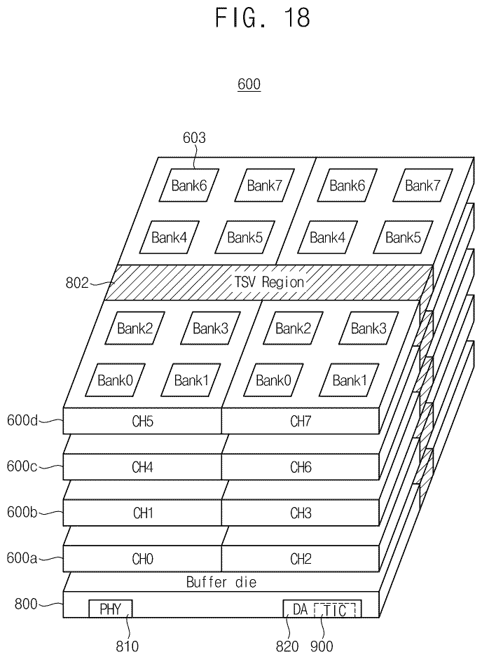

FIG. 17 is a diagram an example of illustrating an example of a semiconductor package.

Referring to FIG. 17, a semiconductor package 500 includes a stacked memory device 600, a system on chip SoC 510, an interposer 550, and a package substrate 560. The stacked memory device 600 may include a buffer die 800 and core dies 600a, 600b, 600c and 600d.

Each of the core dies 600a, 600b, 600c and 600d may include a memory cell array. The buffer die 800 may include a physical region 810 and a direct access region DA 820. The physical region 810 may be electrically connected with a physical region 530 of the system on chip 5100. Through the physical region 810, the stacked memory device 600 may receive signals from the system on chip 510 or may transmit signals to the system on chip 510. The direct access region DA 820 may include a test interface circuit TIC 900.

The direct access region 820 may provide an access path capable of testing the stacked memory device 600 without passing through the system on chip 510. The direct access region 820 may include a conduction means (e.g., a port or a pin) capable of directly communicating with an external test device. A test signal and data received through the direct access region 820 may be transmitted to the core dies 600a, 600b, 600c and 600d through TSVs. To test the core dies 600a, 600b, 600c and 600d, data read from the core dies 600a, 600b, 600c and 600d may be transmitted to the test device through the TSVs and the direct access region 820. As such, a direct access test may be performed with respect to the core dies 600a, 600b, 600c and 600d.

The buffer die 800 and the core dies 600a, 600b, 600c and 600d may be electrically connected through TSV 601 and bumps 602. The buffer die 800 may receive signals, which are provided to each channel through the bumps 602 allocated for each channel, from the system on chip 510. For example, the bumps 602 may be micro-bumps.

The system on chip 510 may execute applications that the semiconductor package 500 supports, by using the stacked memory device 600. For example, the system on chip 510 may include at least one of a central processing unit (CPU), an application processor (AP), a graphic processing unit (GPU), a neural processing unit (NPU), a tensor processing unit (TPU), a vision processing unit (VPU), an image signal processor (ISP), or a digital signal processor (DSP) and may execute specialized calculations.

The system on chip 510 may include the physical region 530 and a memory controller 520. The physical region 530 (e.g., a physical layer) may include input/output circuits for exchanging signals with the physical region 810 of the stacked memory device 600. The system on chip 510 may provide various signals to the physical region 810 through the physical region 530. The signals provided to the physical region 810 may be transferred to the core dies 600a, 600b, 600c and 600d through the interface circuits of the physical region 810 and the TSVs 601.

The memory controller 520 may control overall operations of the stacked memory device 600. The memory controller 520 may provide the stacked memory device 600 with signals for controlling the stacked memory device 600, through the physical region 530.

The interposer 550 may connect the stacked memory device 600 and the system on chip 510. The interposer 550 may connect the physical region 810 of the stacked memory device 600 and the physical region 530 of the system on chip 510 and may provide physical paths formed by using conductive materials. As such, the stacked memory device 600 and the system on chip 510 may be stacked on the interposer 550 and may exchange signals with each other.

The bumps 503 may be attached on an upper surface of the package substrate 560, and solder balls 504 may be attached on a lower surface of the package substrate 560. For example, the bumps 503 may be flip-chip bumps. The interposer 550 may be stacked on the package substrate 560 through the bumps 503. The semiconductor package 500 may exchange signals with any other external package or semiconductor devices through the solder balls 504. For example, the package substrate 560 may be a printed circuit board (PCB).

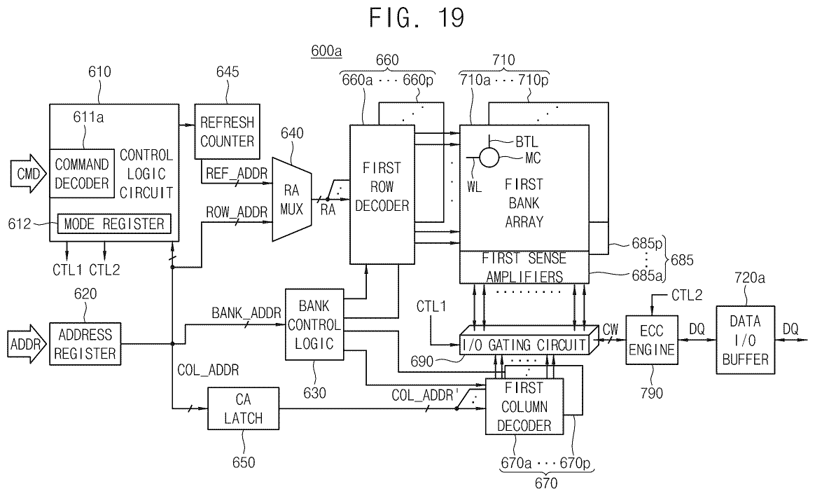

FIG. 18 is a block diagram illustrating an example of the stacked memory device in FIG. 17.

Referring to FIG. 18, the stacked memory device 600 includes a buffer die 800 and a plurality of core dies 600a, 600b, 600c and 600d. For example, the buffer die 800 may be also referred to as an “interface die”, a “base die”, a “logic die”, or a “master die”, and each of the core dies 600a, 600b, 600c and 600d may be also referred to as a “memory die” or a “slave die”. In the example illustrated in FIG. 18, the stacked memory device 600 includes the four core dies 600a, 600b, 600c and 600d, but the number of core dies may be variously changed. For example, the stacked memory device 600 may include 8, 12, or 16 core dies.

The buffer die 800 and the core dies 600a, 600b, 600c and 600d may be stacked and may be electrically connected by using through silicon vias (TSV). As such, the stacked memory device 600 may have a three-dimensional memory structure in which the plurality of dies 600a, 600b, 600c and 600d are stacked. For example, the stacked memory device 600 may be implemented in compliance with the HBM or hybrid memory cube (HMC) standard.

The stacked memory device 600 may support a plurality of channels (or vaults) that are functionally independent of each other. For example, as illustrated in FIG. 17, the stacked memory device 600 may support 8 channels CH0 to CH7. In the case where each of the channels CH0 to CH7 supports 128 DQ input/outputs (I/O) s, the stacked memory device 600 may support 1204 DQ I/Os. However, implementations are not limited thereto. For example, the stacked memory device 70 may support 1024 or more DQ I/Os and may support 8 or more channels (e.g., 16 channels). In the case where the stacked memory device 600 supports 16 channels, each of the channels may support 64 DQ I/Os.

Each of the core dies 600a, 600b, 600c and 600d may support at least one channel. For example, as illustrated in FIG. 18, the core dies 600a, 600b, 600c and 600d may support channel pairs CH0 and CH2, CH1 and CH3, CH4 and CH6, and CH5 and CH7, respectively. In this case, the core dies 600a, 600b, 600c and 600d may support different channels. However, implementations are not limited thereto. For example, at least two of the core dies 600a, 600b, 600c and 600d may support the same channel. For example, each of the core dies 600a, 600b, 600c and 600d may support the first channel CH0.

Each of channels may form an independent command and data interface. For example, channels may be independently clocked based on independent timing requirements and may not be synchronized. For example, based on an independent command, each channel may change a power state or may perform a refresh operation.

Each of the channels may include a plurality of memory banks 603. Each of the memory banks 603 may include memory cells connected with word lines and bit lines, a row decoder, a column decoder, a sense amplifier, etc. For example, as illustrated in FIG. 18, each of the channels CH0 to CH7 may support 8 memory banks 401, such as memory banks Bank0, Bank1, Bank2, Bank3, Bank4, Bank5, Bank6 and Bank7. However, implementations are not limited thereto. For example, each of the channels CH0 to CH7 may support 8 or more memory banks 603. In the example illustrated in FIG. 18, memory banks belonging to one channel are included in one core die, but memory banks belonging to one channel may be distributed into a plurality of core dies. For example, in the case where each of the core dies 600a, 600b, 600c and 600d supports the first channel CH0, memory banks included in the first channel CH0 may be distributed into the core dies 600a, 600b, 600c and 600d.

In some implementations, one channel may be divided into two pseudo channels that operate independently of each other. For example, the pseudo channels may share a command and clock inputs (e.g., a clock signal and a clock enable signal) of the corresponding channel but may independently decode and execute commands. For example, in the case where one channel supports 128 DQ I/Os, each of the pseudo channels may support 64 DQ I/Os. For example, in the case where one channel supports 64 DQ I/Os, each of the pseudo channels may support 32 DQ I/Os.

The buffer die 800 and the core dies 600a, 600b, 600c and 600d each may include a TSV region 802. TSVs 601 may penetrate the core dies 600a, 600b, 600c and 600d and may penetrate the buffer die 800. The TSVs 601 may be disposed in the TSV region 802. The buffer die 800 may exchange signals and/or data with the core dies 600a, 600b, 600c and 600d through the TSVs. Each of the core dies 600a, 600b, 600c and 600d may exchange signals and/or data with the buffer die 800 through the TSVs, and the core dies 600a, 600b, 600c and 600d may exchange signals and/or data with each other through the TSVs. In this case, the signals and/or data may be independently exchanged through the corresponding TSVs for each channel. For example, in the case where an external host device transmits a command and an address to the first channel CH0 for the purpose of accessing a memory cell of the first core die 600a, the buffer die 800 may transmit control signals to the first core die 600a through TSVs corresponding to the first channel CH0 and may access the memory cell of the first channel CH0.

The buffer die 800 may include the physical region 810 and the direct access region 820 and the direct access region 820 may include the test interface circuit 900.

In some implementations, the buffer die 800 may include channel controllers respectively corresponding to channels. A channel controller may manage memory reference operations of the corresponding channel and may determine a timing requirement of the corresponding channel.

In some implementations, the buffer die 800 may include a plurality of pins for receiving signals from the external host device.

FIG. 19 is a block diagram illustrating an example of the first core die in the stacked memory device of FIG. 18.

Referring to FIG. 19, the first core die 600a includes a control logic circuit 610, an address register 620, a bank control logic 630, a row address multiplexer 640, a column address latch 650, a row decoder 660, a column decoder 670, a memory cell array 710, a sense amplifier unit 685, an input/output (I/O) gating circuit 690, a refresh counter 645, a data I/O buffer 720a, and an ECC engine 790.

The memory cell array 710 may include first through sixteenth bank arrays 710a-710p. The row decoder 660 may include first through sixteenth row decoders 660a-660p respectively coupled to the first through sixteenth bank arrays 710a-710p. The column decoder 670 may include first through sixteenth column decoders 670a-670p respectively coupled to the first through sixteenth bank arrays 710a-710p. The sense amplifier unit 685 may include first through sixteenth sense amplifiers 685a-685p respectively coupled to the first through sixteenth bank arrays 710a-710p. The first through sixteenth bank arrays 510a-510p, the first through sixteenth row decoders 660a-660p, the first through sixteenth column decoders 670a-670p, and first through sixteenth sense amplifiers 685a-685p may form first through sixteenth banks.

Each of the first through sixteenth bank arrays 710a-710p may include a plurality of memory cells MC, formed at intersections of a plurality of word-lines WL and a plurality of bit-line BTL.

The address register 620 may receive the address ADDR including a bank address BANK_ADDR, a row address ROW_ADDR, and a column address COL_ADDR from the buffer die 800. The address register 620 may provide the received bank address BANK_ADDR to the bank control logic 630, provide the received row address ROW_ADDR to the row address multiplexer 740, and provide the received column address COL_ADDR to the column address latch 750.

The bank control logic 630 may generate bank control signals in response to the bank address BANK_ADDR. One of the first through sixteenth row decoders 660a-660p corresponding to the bank address BANK_ADDR may be activated in response to the bank control signals, and one of the first through sixteenth column decoders 670a-670p corresponding to the bank address BANK_ADDR may be activated in response to the bank control signals.

The row address multiplexer 640 may receive the row address ROW_ADDR from the address register 620 and may receive a refresh row address REF_ADDR from the refresh counter 645. The row address multiplexer 640 may selectively output one of the row address ROW_ADDR and the refresh row address REF_ADDR as a row address RA. The row address RA that is output from the row address multiplexer 440 may be applied to the first through sixteenth row decoders 660a-660p.

The refresh counter 645 may sequentially increase or decrease the refresh row address REF_ADDR under control of the control logic circuit 610.

The activated one of the first through sixteenth row decoders 660a-660p may decode the row address RA that is output from the row address multiplexer 640 and may activate a word-line corresponding to the row address RA. For example, the activated bank row decoder may apply a word-line driving voltage to the word-line corresponding to the row address RA.

The column address latch 650 may receive the column address COL_ADDR from the address register 620 and may temporarily store the received column address COL_ADDR. In some implementations, in a burst mode, the column address latch 650 may generate column addresses COL_ADDR′ that increment from the received column address COL_ADDR. The column address latch 650 may apply the temporarily stored or generated column address COL_ADDR′ to the first through sixteenth column decoders 670a-670p.

The activated one of the first through sixteenth column decoders 670a-670p may decode the column address COL_ADDR′ that is output from the column address latch 650 and may control the I/O gating circuit 690 to output data corresponding to the column address COL_ADDR.

The I/O gating circuit 690 may include circuitry for gating input/output data. The I/O gating circuit 690 may further include read data latches for storing data that is output from the first through sixteenth bank arrays 710a-710p and write drivers for writing data to the first through sixteenth bank arrays 710a-710p.

A codeword CW that is read from one bank array of the first through sixteenth bank arrays 710a-710p may be sensed by a sense amplifier coupled to the one bank array from which the data is to be read, and may be stored in the read data latches. The codeword CW stored in the read data latches may be provided to the ECC engine 790. The ECC engine 790 may perform an ECC decoding on the codeword CW to provide the data DQ to the data I/O buffer 720a. The data I/O buffer 720a may transmit the data DQ to the buffer die 800.

The data DTA to be written in one bank array of the first through sixteenth bank arrays 710a-710p may be provided to the ECC engine 790 from the data I/O buffer 720a. The ECC engine 790 may perform an ECC encoding on the data DQ to generate parity bits and the ECC engine 790 may provide the data DQ and the parity bits to the I/O gating circuit 690. The I/O gating circuit 690 may write the data DQ and the parity bits in a sub-page in one bank array through the write drivers.

The ECC engine 790 may perform an ECC encoding and ECC decoding on the data DTA based on a second control signal CTL2 from the control logic circuit 610.

The control logic circuit 610 may control operations of the first core die 600a. The control logic circuit 610 may include a command decoder 611a that decodes the command CMD received from the buffer die 800 and may include a mode register 612 that sets an operation mode of the first core die 600a.

The control logic circuit 610 may generate a first control signal CTL1 to control the I/O gating circuit 690 and may generate the second control signal CTL2 to control the ECC engine 790 by decoding the command CMD.

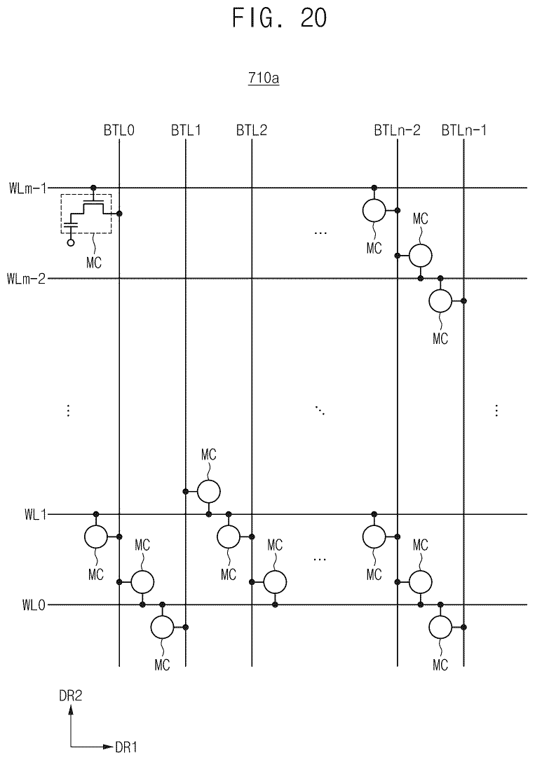

FIG. 20 illustrates an example of a first bank array in the first core die of FIG. 19.

Referring to FIG. 20, the first bank array 710a includes a plurality of word-lines WL0-WLm−1 (m is a natural number greater than two), a plurality of bit-lines BTL0-BTLn−1 (n is a natural number greater than two), and a plurality of memory cells MCs disposed at intersections between the word-lines WL0-WLm−1 and the bit-lines BTL0-BTLn−1. Each of the memory cells MCs may include a cell transistor coupled to each of the word-lines WL0-WLm−1 and each of the bit-lines BTL0-BTLn−1 and a cell capacitor coupled to the cell transistor. Each of the memory cells MCs may have a DRAM cell structure. Each of the word-lines WL0-WLm−1 extends in a first direction DR1, and each of the bit-lines BTL1-BTLn−1 extends in a second direction DR2 crossing the first direction DR1.

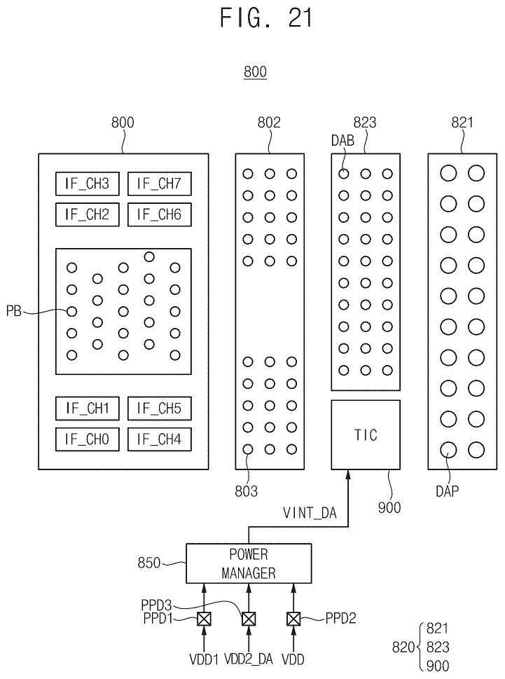

The word-lines WL0-WLm−1 coupled to the plurality of memory cells MCs may be referred to as rows of the first bank array 710a, and the bit-lines BTL0-BTLn−1 coupled to the plurality of memory cells MCs may be referred to as columns of the first bank array 710a. FIG. 21 is a block diagram illustrating an example of the buffer die in FIG. 17.

Referring to FIG. 21, the buffer die 800 includes the physical region 810, the TSV region 802, the direct access region 820 and a power manager 850.

A plurality of PHY bumps PB and a plurality of channel interface circuits IF_CH0-IF_CH7 for interfacing with the channels CH0 to CH7 of the core dies 600a, 600b, 600c and 600d 20 may be formed on the physical region 810. A plurality of TSVs 803 may be formed on the TSV region 802.

The direct access region 820 may include a DA probing region 821, a DA bump region 823 and the test interface circuit 900.

In the DA bump region 823, a plurality of DA bumps DAB for interfacing with the external test device through the interposer 550 to test the stacked memory device 600, may be formed. In the DA probing region 821, a plurality of DA pads DAP for interfacing with the external test device without going through the interposer 550 to test the stacked memory device 600, may be formed. The PHY bumps PB and the DA bumps DB may be formed of micro-bumps, and the DA pads DAP may be formed of pad larger than the micro-bumps. For example, the DA pads DAP may be larger in physical size but fewer in number compared to the PHY bumps PB and the DA bumps DB.

In the direct access mode, a test signal may be transferred to the physical region 810 through the DA bumps DAB or the DA pads DAP of the direct access region 820, and, then transferred to each of the core dies 600a, 600b, 600c and 600d through the TSVs 803 of the TSV region 802 by the channel interface circuits IF_CH0 to IF_CH7 in the physical region 810. Herein, there is a high possibility that a skew may occur between test signals because the physical region 810 is physically far away from the direct access region 820. Therefore, it may be necessary to transfer test signals at an exact timing between the direct access region 820 and the physical region 810. Further, when the test signals are applied through the DA bumps DAB or DA pads DAP, an internal test operation may be constrained by the operating speed of the external test device. For example, if the external test device is operating at low speed, the test operation may be performed by placing a clock frequency doubler inside the buffer die 800a. However, a duty ratio of complementary clocks generated by such a clock frequency doubler may be not constant and a cross-point of the complementary clocks may be not centered, causing the characteristics of the test operation to be degraded. For example, when a high-speed test is performed on a conventional semiconductor memory device including a direct access region, because an individual power supply voltage is not applied to the direct access region, a sensitivity to a power supply voltage increases and a test performance is degraded because difference of margins of the test control signal occurs due to duty ratio of internal clock signal generated based on an external clock signal is not constant.

To solve these problems, the direct access region 820 includes the test interface circuit 900.

The test interface circuit 900, in the direct access mode, may receive an external clock signal and a test control signal from an external test device, may generate an internal clock signal based on an external clock signal, may generate a first internal test control signal by latching the test control signal at a first timing point of the internal clock signal, may generate a second internal test control signal by latching the first internal test control signal at a second timing point of the internal clock and may provide the physical region 810 with one of the first internal test control signal and the second internal test control signal as an internal test control signal. The internal clock signal may have different duties at the first timing point and the second timing point. A frequency of the internal clock signal may be two times greater than a frequency of the external clock signal.

Therefore, the stacked memory device 600, in the direct access mode, may perform a high-speed test while adjusting timing point of transferring the internal clock signal to the physical region 810.

The power manager 850 may receive a first power supply voltage VDD1 through a first power pad PPD1, may receive a second power supply voltage VDD2 through a second power pad PPD2, may generate an internal power supply voltage VINT_DA based on one of the first power supply voltage VDD1 and the second power supply voltage VDD2 and may supply the internal power supply voltage VINT_DA to the direct access region 820.

The first power supply voltage VDD1 and the second power supply voltage VDD2 may be supplied to a memory cell array in each of the core dies 600a, 600b, 600c and 600d and the second power supply voltage VDD2 may be supplied to the peripheral circuit and the physical region 810 in each of the core dies 600a, 600b, 600c and 600d.

A voltage level of the first power supply voltage VDD1 may be greater than a voltage level of the second power supply voltage VDD2.

In some implementations, the power manager 850 may receive a dedicated power supply voltage VDD2_DA through a dedicated, may generate the internal power supply voltage VINT_DA by power-gating the dedicated power supply voltage VDD2_DA and provide the internal power supply voltage VINT_DA to the direct access region 820.

The power manager 850 may employ one of the power manager 400 of FIG. 4, the power manager 400b of FIG. 6 and the power manager 400c of FIG. 7.

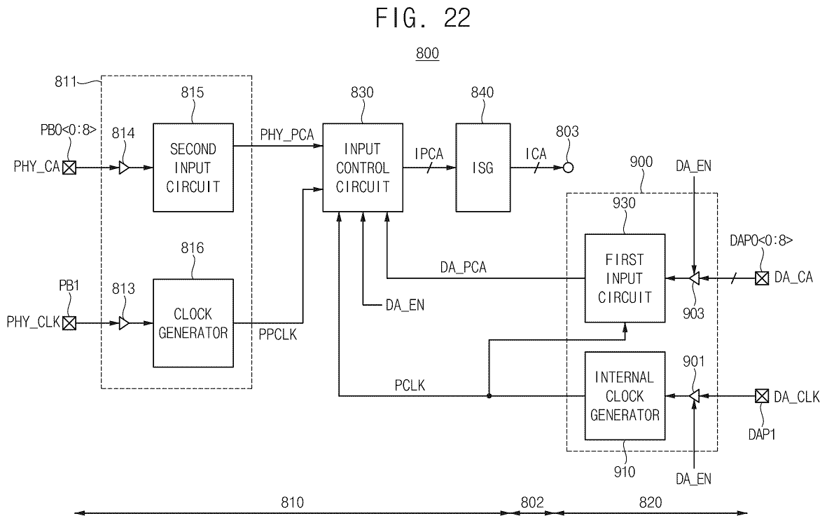

FIG. 22 illustrates an example of the buffer die in FIG. 18.

Referring to FIG. 22, the buffer die 800 includes the physical region 810, the direct access region 820 and the TSV region 802.

On the physical region 810, a plurality of first PHY bumps PB0<0:8> for receiving a normal control signal PHY_CA, and a second PHY bump PB1 for receiving a normal clock PHY_CA, during a normal operation, may be disposed.

On the direct access region 820, a plurality of first DA pads DAP0<0:8> for receiving the test control signal DA_CA, and a second DA pad DAP1 for receiving the external clock DA_CLK may be disposed. The test interface circuit 900 may be disposed in the direct access region 820.

The test interface circuit 900 may include the buffers 901 and 903, an internal clock generator 910 and a first input circuit 930. The buffer 901 may be enabled in response to the mode signal DA_EN designating the direct access mode and may provide the internal clock generator 910 with an external clock signal DA_CLK received from the external test device. The buffer 903 may be enabled in response to the mode signal DA_EN designating the direct access mode and may provide the first input circuit 930 with the test control signal DA_CA received from the external test device.

The first input circuit 930 may employ the first input circuit 330 in FIG. 9 and the internal clock generator 910 may employ the internal clock generator 310 in FIG. 9.

Therefore, the internal clock generator 910, in the direct access mode, may generate an internal clock signal PCLK based on the external clock signal DA_CLK and may provide the internal clock signal PCLK to the first input circuit 930 and an input control circuit 830 in the physical region 810. The first input circuit 930, in the direct access mode, may generate the internal test control signal DA_PCA by delaying the test control signal DA_CA at least once based on the internal clock signal PCLK and may transfer the internal test control signal DA_PCA to the input control circuit 830 in the physical region 210.

The physical region 810 may include an interface circuit 811, the input control circuit 830 and an internal signal generator 840. Each of the interface circuit 811, the input control circuit 830 and an internal signal generator 840 may respectively employ the interface circuit 211, the input control circuit 230 and the internal signal generator 240 in FIG. 15.

The interface circuit 811 may include buffers 813 and 814, a second input circuit 815 and a clock generator 816.

The buffer 813, in the normal mode, may receive a clock signal PHY_CLK and may provide the clock signal PHY_CLK to the clock generator 816. The clock generator 816 may generate a normal clock signal PPCLK based on the clock signal PHY_CLK and may provide the normal clock signal PPCLK to the second input circuit 815 and the input control circuit 830.

The buffer 814, in the normal mode, may receive a normal control signal PHY_CA and may provide the normal control signal PHY_CA to the second input circuit 815. The second input circuit 815 may generate an internal normal control signal PHY_PCA based on the normal clock signal PPCLK and may transfer the internal normal control signal PHY_PCA to the input control circuit 830.

The input control circuit 830 may receive the mode signal DA_EN, the internal clock signal PCLK, the internal test control signal DA_PCA, the normal clock signal PPCLK and the internal normal control signal PHY_PCA.

The input control circuit 830, in response to the mode signal DA_EN designating the direct access mode, may select the internal test control signal DA_PCA of the internal test control signal DA_PCA and the internal normal control signal PHY_PCA, may generate a selected control signal IPCA by latching the internal test control signal DA_PCA based on the internal clock signal PCLK and may provide the selected control signal IPCA to the internal signal generator 840.

The input control circuit 830, in response to the mode signal DA_EN designating the normal mode, may select the internal normal control signal PHY_PCA of the internal test control signal DA_PCA and the internal normal control signal PHY_PCA, may generate a selected control signal IPCA by latching the internal normal control signal PHY_PCA based on the normal clock signal PPCLK and may provide the selected control signal IPCA to the internal signal generator 840.

The internal signal generator 840 may generate internal signals ICA based on the selected control signal IPCA and may provide the internal signals ICA to the TSVs 803.

The test interface circuit 900 may generate internal test data by latching a test data and may provide the internal test data to the input control circuit 830, the interface circuit 811 may generate an internal normal data by latching a normal data and may provide the internal normal data to the input control circuit 830. The input control circuit 830, in the direct access mode, may provide the internal test data to the core dies 600a, 600b, 600c and 600d through TSV 803 and, in the normal mode, may provide the internal normal data to the core dies 600a, 600b, 600c and 600d through TSV 803.

The first input circuit 930 may employ the first input circuit 330a in FIG. 12 or the first input circuit 330b in FIG. 13.

Therefore, the first input circuit 930, in the direct access mode, may generate the first internal test control signal and the second internal test control signal by latching the test control signal DA_CA at least two times based on the internal clock signal PCLK and may provide the physical region 810 with one of the first internal test control signal and the second internal test control signal as an internal test control signal based on a selection signal. Therefore, the first input circuit 930, in the direct access mode, may perform a test with respect to various timing margins by adjusting timing point of transferring the internal test control signal to the physical region 810.

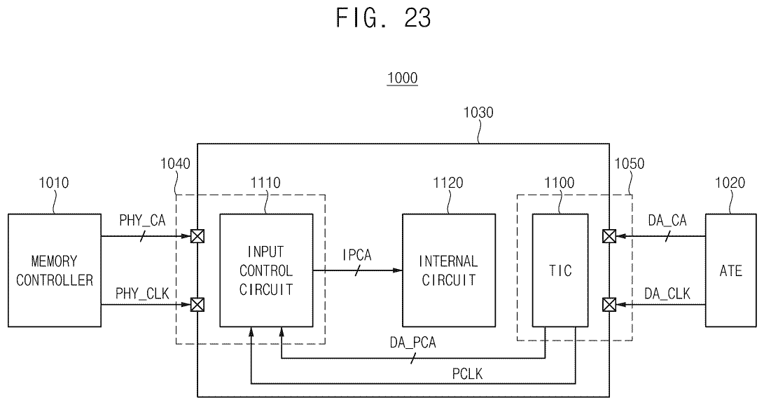

FIG. 23 is a block diagram illustrating an example of a semiconductor system.

Referring to FIG. 23, a semiconductor system 1000 includes a memory controller 1010, a test device ATE 1020 and a semiconductor memory device 1030.

The test device 1020 may provide an external clock signal DA_CLK and a test control signal DA_CA to the semiconductor memory device 1030 during a test operation.

The memory controller 1010 may provide a clock signal PHY_CLK and a normal control signal PHY_CA to the semiconductor memory device 1030 during a normal operation.

The semiconductor memory device 1030 may perform the test operation based on the external clock signal DA_CLK and the test control signal DA_CA and perform the normal operation based on the clock signal PHY_CLK and the normal control signal PHY_CA. The semiconductor memory device 1030 may include the semiconductor memory device 200 of FIG. 2 or the stacked memory device 600 of FIG. 18.

The semiconductor memory device 1030 may include a physical region 1040 interfacing with the memory controller 1010 and a direct access region 1050 interfacing directly with the test device 1020.

The semiconductor memory device 1030 may receive the external clock signal DA_CLK and the test control signal DA_CA from the test device 1020 via the direct access region 1050 and may receive clock signal PHY_CLK and the normal control signal PHY_CA from the memory controller 1010 via the physical region 1040.

The direct access region 1050 may include a test interface circuit 1100. The physical region 1040 may include an input control circuit 1110 and the semiconductor memory device 1030 may further include an internal circuit 1120.

The test interface circuit, in the direct access mode, may receive external clock signal DA_CLK and the test control signal DA_CA from the test device 1020, may generate an internal clock signal PCLK based on the external clock signal DA_CLK, may generate a first internal test control signal by latching the test control signal DA_CA at a first timing point of the internal clock signal PCLK, may generate a second internal test control signal by latching the first internal test control signal at a second timing point of the internal clock DA_CA and may provide the input control circuit 1110 in the physical region 1040 with one of the first internal test control signal and the second internal test control signal as an internal test control signal DA_PCA. The internal clock signal PCLK may have different duties at the first timing point and the second timing point. A frequency of the internal clock signal may be two times greater than a frequency of the external clock signal.

Therefore, the semiconductor memory device 1030, in the direct access mode, may perform a high-speed test while adjusting timing point of transferring the internal clock signal to the physical region 1040.

The input control circuit 1110, in response to the mode signal DA_EN designating the direct access mode, may select the internal test control signal DA_PCA of the internal test control signal DA_PCA and an internal normal control signal PHY_PCA, may generate a selected control signal IPCA by latching the internal test control signal DA_PCA based on the internal clock signal PCLK and may provide the selected control signal IPCA to the internal circuit 1120.

The input control circuit 1110, in response to the mode signal DA_EN designating the normal mode, may select the internal normal control signal PHY_PCA of the internal test control signal DA_PCA and the internal normal control signal PHY_PCA, may generate a selected control signal IPCA by latching the internal normal control signal PHY_PCA based on the normal clock signal and may provide the selected control signal IPCA to the internal circuit 1120.

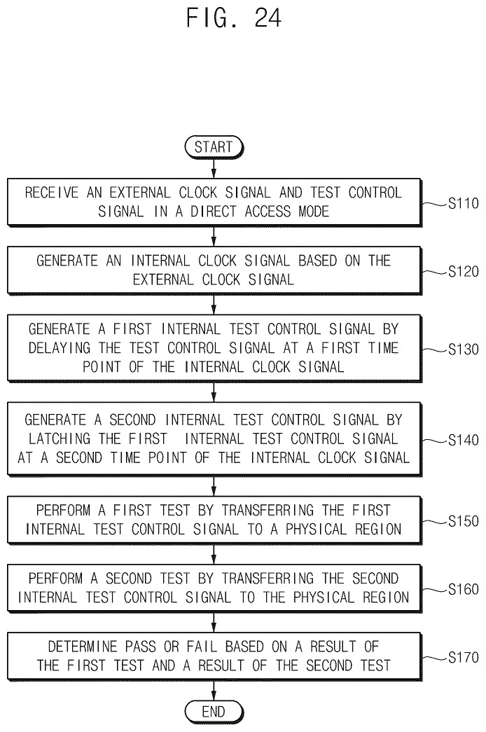

FIG. 24 is a flow chart illustrating an example of a method of testing a semiconductor memory device.

Referring to FIGS. 1, 2, 9-16 and 24, the test interface circuit 300 disposed in the direct access region 220 of the semiconductor memory device 200 receives an external clock signal DA_CLK and a test control signal DA_CA from an external test device in the direct access mode (operation S110).

The test interface circuit 300 generates an internal clock signal PCLK based on the external clock signal DA_CLK (operation S120). The test interface circuit 300 generates a first internal test control signal DA_CA1 by latching the test control signal DA_CA at a first timing point of the internal clock signal PCLK (operation S130). The test interface circuit 300 generates a second internal test control signal DA_CA2 by latching the first internal test control signal DA_CA1 at a second timing point of the internal clock signal PCLK (operation S140).

The test interface circuit 300 performs a first test based on the first internal test control signal DA_CA1 by transferring the first internal test control signal DA_CA1 to the physical region 210 (operation S150). The test interface circuit 300 performs a second test based on the second internal test control signal DA_CA2 by transferring the second internal test control signal DA_CA2 to the physical region 210 (operation S160).

The external test device determines whether the semiconductor memory device 200 passes or fails based on a result of the first test and a result of the second test (operation S170).

The external test device determines passing of the test when the semiconductor memory device 200 passes both the first test and the second test and determines failing of the test when the semiconductor memory device 200 passes one of the first test and the second test

The foregoing examples may be applied to systems using semiconductor memory devices and stacked memory devices. While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to example embodiments thereof, it will be apparent to those of ordinary skill in the art that many modifications in form and details may be made thereto without materially departing from the spirit and scope of the present disclosure as set forth by the following claims.

What is claimed is:

1. A semiconductor memory device comprising:
a physical region configured to interface with an external memory controller;
a direct access region configured to interface with an external test device; and
a power manager configured to (i) generate an internal power supply voltage based on at least one of a first power supply voltage, a second power supply voltage, or a power supply voltage and (ii) provide the internal power supply voltage to the direct access region, the first power supply voltage and the second power supply voltage being provided from outside the semiconductor memory device and the power supply voltage being received through a power pad,
wherein the power manager is configured to provide the second power supply voltage to the physical region,
wherein the direct access region includes a test interface circuit, and
wherein the test interface circuit is configured to:
generate an internal clock signal based on an external clock signal received from the external test device,
generate an internal test control signal by latching a test control signal based on the internal clock signal, the test control signal being received from the external test device, and
provide the internal test control signal to the physical region.

2. The semiconductor memory device of claim 1, further comprising:
a memory region including a plurality of memory cell arrays; and
a peripheral circuit region including a plurality of peripheral circuits configured to control the plurality of memory cell arrays, respectively,
wherein the memory region is configured to operate based on the first power supply voltage and the second power supply voltage, and
wherein the peripheral circuit region is configured to operate based on the second power supply voltage.

3. The semiconductor memory device of claim 2, wherein the physical region includes a plurality of channel interface circuits, and
wherein each of the plurality of channel interface circuits is configured to interface with respective one of the plurality of memory cell arrays through respective one of the plurality of peripheral circuits.

4. The semiconductor memory device of claim 1, wherein the power manager includes:
a comparator configured to generate a regulation voltage by comparing a reference voltage and the internal power supply voltage; and
a power transistor coupled between the first power supply voltage and an output node, the power transistor configured to generate the internal power supply voltage by regulating the first power supply voltage based on the regulation voltage.

5. The semiconductor memory device of claim 4, wherein the power transistor includes:
a source coupled to the first power supply voltage,
a gate configured to receive the regulation voltage, and
a drain coupled to the output node and configured to provide the internal power supply voltage.

6. The semiconductor memory device of claim 1, wherein the power manager includes:
a voltage detector configured to generate a decision signal by comparing the internal power supply voltage with a reference voltage in a direct access mode;
an oscillator configured to generate a pumping clock signal by performing an oscillation operation based on the decision signal; and
a charge pump configured to generate the internal power supply voltage by performing a pumping operation based on the pumping clock signal and the second power supply voltage, and
wherein the voltage detector is configured to be enabled based on the direct access mode being activated.

7. The semiconductor memory device of claim 1, wherein the power manager includes a power transistor,
wherein, in a direct access mode, the power transistor is configured to generate the internal power supply voltage by power-gating the power supply voltage, and
wherein, in a normal mode, the power transistor is configured to cut off the power supply voltage.

8. The semiconductor memory device of claim 1, wherein the test interface circuit is configured to:
generate a first internal test control signal by latching the test control signal at a first timing point of the internal clock signal;
generate a second internal test control signal by latching the first internal test control signal at a second timing point of the internal clock; and
provide the physical region with at least one of the first internal test control signal or the second internal test control signal as the internal test control signal, and
wherein the internal clock signal has different duties at the first timing point and the second timing point.

9. A semiconductor memory device comprising:
a physical region configured to interface with an external memory controller; and
a direct access region configured to interface with an external test device directly,
wherein the direct access region includes a test interface circuit, and
wherein the test interface circuit is configured to:
generate an internal clock signal based on an external clock signal received from the external test device,
generate a first internal test control signal by latching a test control signal received from the external test device at a first timing point of the internal clock signal,
generate a second internal test control signal by latching the first internal test control signal at a second timing point of the internal clock, and
provide the physical region with at least one of the first internal test control signal and the second internal test control signal as an internal test control signal,
wherein the internal clock signal has different duties at the first timing point and the second timing point.

10. The semiconductor memory device of claim 9, wherein the test interface circuit includes:
an internal clock generator configured to, in a direct access mode, generate the internal clock signal based on the external clock signal; and
an input circuit configured to, in the direct access mode, generate the internal test control signal by delaying the test control signal at least once based on the internal clock signal.

11. The semiconductor memory device of claim 10, wherein the internal clock generator includes:
a phase shifter configured to generate a first intermediate clock signal and a second intermediate clock signal having a phase difference of 90 degrees with respect to each other by shifting a phase of the external clock signal; and
an XOR gate configured to generate the internal clock signal by performing an XOR operation on the first intermediate clock signal and the second intermediate clock signal, and
wherein a frequency of the internal clock signal is two times greater than a frequency of the external clock signal.

12. The semiconductor memory device of claim 10, wherein the input circuit includes:
a first D-flipflop configured to output the first internal test control signal by latching the test control signal at the first timing point of the internal clock signal;
a second D-flipflop configured to output the second internal test control signal by latching the second internal test control signal at the second timing point of the internal clock signal; and
a multiplexer configured to output the first internal test control signal or the second internal test control signal as the internal test control signal based on a selection signal.

13. The semiconductor memory device of claim 12, wherein:
a first duty ratio of the internal clock signal at the first timing point is smaller than 50%; and
a second duty ratio of the internal clock signal at the second timing point is greater than 50%.

14. The semiconductor memory device of claim 12, wherein the first D-flipflop is configured to generate the first internal test control signal by delaying the test control signal by a half period of the external clock signal based on the internal clock signal, and
wherein the second D-flipflop is configured to generate the second internal test control signal by delaying the test control signal by a period of the external clock signal based on the internal clock signal.

15. The semiconductor memory device of claim 14, wherein the semiconductor memory device is configured to select the first timing point or the second timing point by setting the selection signal by a test mode register set.

16. The semiconductor memory device of claim 10, wherein the physical region includes:
an interface circuit configured to, in a normal mode, generate an internal normal control signal based on a normal signal received from the external memory controller and generate a normal clock signal based on a clock signal received from the external memory controller;
an input control circuit configured to select the internal clock signal or the normal clock signal as a selected clock signal based on a selection signal designating one of the direct access mode or the normal mode, wherein the input control circuit is configured to provide the internal test control signal or the internal normal control signal as a selected control signal based on the selected clock signal; and
an internal signal generator configured to generate an internal signal based on the selected control signal and provide the internal signal to a peripheral circuit region.

17. The semiconductor memory device of claim 9, further comprising:
a power manager configured to generate an internal power supply voltage based on a power supply voltage and supply the internal power supply voltage to the direct access region, the power supply voltage being received through a power pad from an outside, and
wherein the power manager includes a power switch,
wherein, in a direct access mode, the power switch is configured to generate the internal power supply voltage by power-gating the power supply voltage; and
wherein, in a normal mode, the power switch is configured to cut off the power supply voltage.

18. A stacked memory device comprising:
a buffer die including an interface circuit and a test interface circuit, wherein the interface circuit is configured to communicate with an external host device in a normal mode, and wherein the test interface circuit is configured to interface with an external test device directly in a direct access mode; and
a plurality of core dies stacked on the buffer die and connected to the buffer die through a plurality of through silicon vias (TSVs),
wherein the buffer die includes a physical region, a direct access region, and a TSV region,
wherein the interface circuit is disposed in the physical region, the test interface circuit is disposed in the direct access region, and the TSVs are formed in the TSV region,
wherein the test interface circuit is configured to, in a direct access mode:
generate an internal clock signal based on an external clock signal received from the external test device,
generate a first internal test control signal by latching a test control signal received from the external test device at a first timing point of the internal clock signal,
generate a second internal test control signal by latching the first internal test control signal at a second timing point of the internal clock, and
provide the physical region with at least one of the first internal test control signal or the second internal test control signal as an internal test control signal,
wherein the internal clock signal has different duties at the first timing point and the second timing point.

19. The stacked memory device of claim 18, wherein the test interface circuit includes:
an internal clock generator configured to, in the direct access mode, generate the internal clock signal based on the external clock signal; and
an input circuit configured to, in the direct access mode, generate the internal test control signal by delaying the test control signal at least once based on the internal clock signal.

20. The stacked memory device of claim 18, wherein the buffer die further includes a power manager configured to generate an internal power supply voltage based on at least one of a first power supply voltage, a second power supply voltage, or a power supply voltage, and configured to supply the internal power supply voltage to the direct access region,
wherein the first power supply voltage is provided to the core dies, the second power supply voltage is provided to the physical region and the power supply voltage is received from outside the stacked memory device through a power pad.
